(19) United States
(12) Patent Application Publication
(10) Pub. No.: US 2018/0204807 A1
(43) Pub. Date: Jul. 19, 2018

(54) SEMICONDUCTOR DEVICE

(71) Applicant: SHINKO ELECTRIC INDUSTRIES CO., LTD., Nagano-shi (JP)

(72) Inventor: Mitsuhiro Aizawa, Nagano-shi (JP)

(21) Appl. No.: 15/866,725

(22) Filed: Jan. 10, 2018

(30) Foreign Application Priority Data
Jan. 13, 2017 (JP) 2017-004445

(51) Int. Cl. H01L 23/00; H01L 23/498

(52) U.S. Cl. CPC H01L 23/562; H01L 23/49822; H01L 23/49816

(57) ABSTRACT

A semiconductor device includes: a circuit board including a substrate made of an inorganic material, and a resin insulating layer formed on the substrate; a semiconductor element mounted on a main face of the circuit board through a bump; and a resin layer formed on the main face to extend along sides or diagonal lines of the circuit board, wherein a thermal expansion of the resin layer is larger than that of the substrate.

This application claims priority from Japanese Patent Application No. 2017-004445, filed on Jan. 13, 2017, the entire contents of which are herein incorporated by reference.

### BACKGROUND

### 1. Technical Field

The present disclosure relates to a semiconductor device.

### 2. Background Art

As a semiconductor element such as a CPU (Central Processing Unit) or a memory is miniaturized, a pitch between adjacent ones of electrode pads of the semiconductor element is also made narrower and narrower. When the semiconductor element is intended to be mounted on a wiring substrate, connection between the both becomes difficult because a pitch between adjacent ones of electrode pads of the wiring substrate is wider than that of the semiconductor element.

To solve the problem, the following technique has been studied. That is, a circuit board called interposer is disposed between the wiring substrate and the semiconductor element, so that the difference in electrode pad pitch between the wiring substrate and the semiconductor element is absorbed by the interposer (e.g. see JP-A-2004-071719).

However, a warp occurs in the circuit board such as the interposer. Thus, there is room for improvement in order to suppress the warp of the circuit board such as the interposer.

### SUMMARY

According to one or more aspects of the present disclosure, there is provided a semiconductor device.

The semiconductor device comprises:

a circuit board comprising a substrate made of an inorganic material, and a resin insulating layer formed on the substrate;

a semiconductor element mounted on a main face of the circuit board through a bump; and

a resin layer formed on the main face to extend along sides or diagonal lines of the circuit board, wherein a thermal expansion of the resin layer is larger than that of the substrate.

### BRIEF DESCRIPTION OF DRAWINGS

FIGS. 1A and 1B are sectional views in a process of manufacturing a semiconductor device used in a study (Part 1);

FIGS. 2A and 2B are sectional views in the process of manufacturing the semiconductor device used in the study (Part 2);

FIGS. 3A and 3B are sectional views in the process of manufacturing the semiconductor device used in the study (Part 3);

FIG. 4 is a sectional view in the process of manufacturing the semiconductor device used in the study (Part 4);

FIG. 5 is a sectional view in the process of manufacturing the semiconductor device used in the study (Part 5);

FIGS. 6A and 6B are sectional views in a process of manufacturing a semiconductor device according to a first embodiment (Part 1);

FIGS. 7A and 7B are sectional views in the process of manufacturing the semiconductor device according to the first embodiment (Part 2);

FIGS. 8A and 8B are sectional views in the process of manufacturing the semiconductor device according to the first embodiment (Part 3);

FIGS. 9A and 9B are sectional views in the process of manufacturing the semiconductor device according to the first embodiment (Part 4);

10 is a sectional view in the process of manufacturing the semiconductor device according to the first embodiment (Part 5);

FIG. 11 is a sectional view in the process of manufacturing the semiconductor device according to the first embodiment (Part 6);

FIG. 12 is a sectional view in the process of manufacturing the semiconductor device according to the first embodiment (Part 7);

FIG. 13 is a plan view showing a planar layout of a resin layer according to a first example of the first embodiment;

FIG. 14 is a plan view showing a planar layout of a resin layer according to a second example of the first embodiment;

FIG. 15 is a plan view showing a planar layout of a resin layer according to a third example of the first embodiment;

FIG. 16 is a plan view showing a planar layout of a resin layer according to a fourth example of the first embodiment;

FIG. 17 is a plan view showing a planar layout of a resin layer according to a fifth example of the first embodiment;

FIG. 18 is a sectional view for explaining an examination which has been conducted by the present inventor

FIG. 19 is a graph showing measurement results of warp amounts;

FIGS. 20A and 20B are sectional views in a process of manufacturing a semiconductor device according to a second embodiment (Part 1);

FIGS. 21A and 21B are sectional views in the process of manufacturing the semiconductor device according to the second embodiment (Part 2);

FIGS. 22A and 22B are sectional views in the process of manufacturing the semiconductor device according to the second embodiment (Part 3);

FIGS. 23A and 23B are sectional views in a process of manufacturing a semiconductor device according to a third embodiment (Part 1);

FIGS. 24A and 24B are sectional views in the process of manufacturing the semiconductor device according to the third embodiment (Part 2); and

FIG. 25 is a sectional view in the process of manufacturing the semiconductor device according to the third embodiment (Part 3).

### DETAILED DESCRIPTION

A matter which has been studied by the present inventor will be described prior to description of embodiments of the invention.

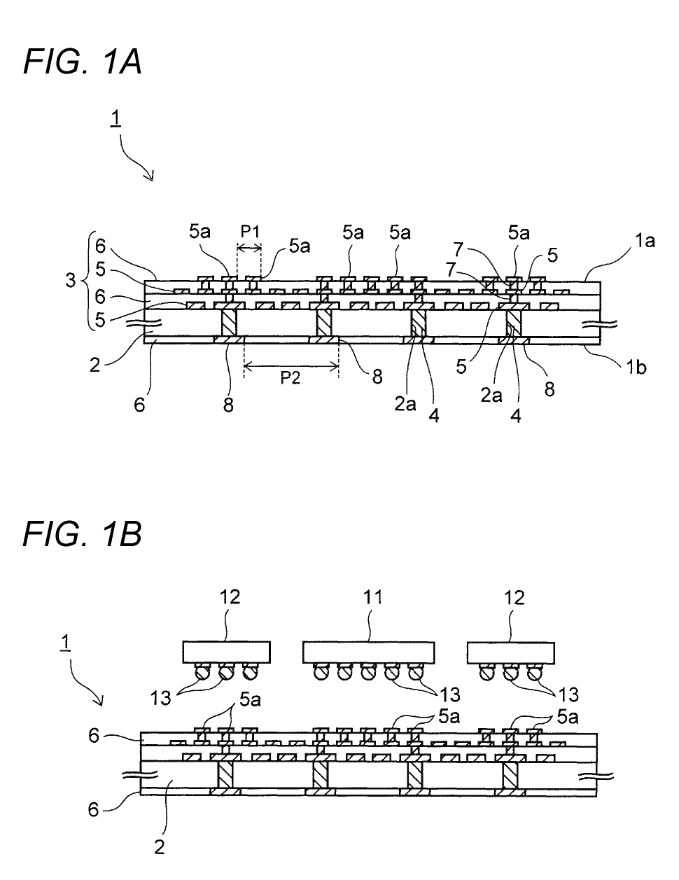

FIGS. 1A and 1B, FIGS. 2A and 2B, FIGS. 3A and 3B and FIGS. 4 and 5 are sectional views in a process of manufacturing a semiconductor device used in the study.

The semiconductor device includes an interposer provided between semiconductor elements and a wiring substrate. The semiconductor device will be manufactured as follows.

First, a circuit board 1 shown in FIG. 1A is prepared. The circuit board 1 is an interposer in which a multilayer wiring layer 3 is formed on a substrate 2.

In the circuit board 1, the substrate 2 is a silicon substrate or a glass substrate which can be micromachined easily. The substrate 2 is about 50 μm to 300 μm thick. A plurality of through holes 2a are formed in the substrate 2. Each of the through holes 2a is filled with a through electrode 4. The material of the through electrode 4 is not limited particularly. Copper excellent in electric conductivity may be used as the material of the through electrode 4.

On the other hand, the multilayer wiring layer 3 includes a plurality of wiring layers 5 and a plurality of resin insulating layers 6 which are formed alternately to one another in the named order.

A copper layer about 1 μm to 3 μm thick is patterned to form each of the wiring layers 5. The wiring layers 5 which are adjacent to one another vertically are electrically connected to one another through via conductors 7 made of copper etc. In addition, each of the resin insulating layers 6 is an epoxy-based resin layer about 5 μm to 8 μm thick. Incidentally, a polyimide resin may be used as the material of the resin insulating layer 6.

Of the wiring layers 5, one formed as an uppermost layer in the multilayer wiring layer 3 functions as first electrode pads 5a on which semiconductor elements which will be described later can be mounted. In addition, the uppermost resin insulating layer 6 functions as a solder resist layer in order to prevent solder from getting wet and spreading.

Further, a plurality of second electrode pads 8 connected to the through electrodes 4 respectively are formed on a back surface of the substrate 2. A copper layer about 3 μm to 5 μm thick is patterned to form the second electrode pads 8 in a similar manner to or the same manner as the first electrode pads 5a. The aforementioned resin insulating layer 6 is formed as a solder resist layer surrounding the second electrode pads 8.

According to such a circuit board 1, the first electrode pads 5a are formed at a first pitch P1 on one main face 1a, and the second electrode pads 8 are formed at a second pitch P2 on the other main face 1b.

In this example, the first pitch P1 is made narrower than the second pitch P2. With this configuration, while the semiconductor elements provided with microfine solder bumps can be connected to the first electrode pads 5a, a wiring substrate which will be described later can be connected to the second electrode pads 8.

Particularly, glass or silicon which can be micromachined easily is used as the material the substrate 2 as in this example. Thus, the through holes 2a or each of the wiring layers 5 can be made microfine so that the circuit board 1 corresponding to miniaturization of the semiconductor dements can be obtained.

Next, as shown in FIG. 1B, first and second semiconductor elements 11 and 12 are disposed above the circuit board 1, and solder bumps 13 of the semiconductor elements 11 and 12 are aligned with the first electrode pads 5a.

The kind of each semiconductor element 11, 12 is not limited particularly. this example, a CPU is used as the first semiconductor element 11, a memory such as a DRAM (Dynamic Random Access Memory) is used as each of the second semiconductor elements 12.

In addition, in each semiconductor element 11, 12, transistors or wirings are formed on a front surface of a silicon substrate. The main material of the semiconductor element 11, 12 is silicon.

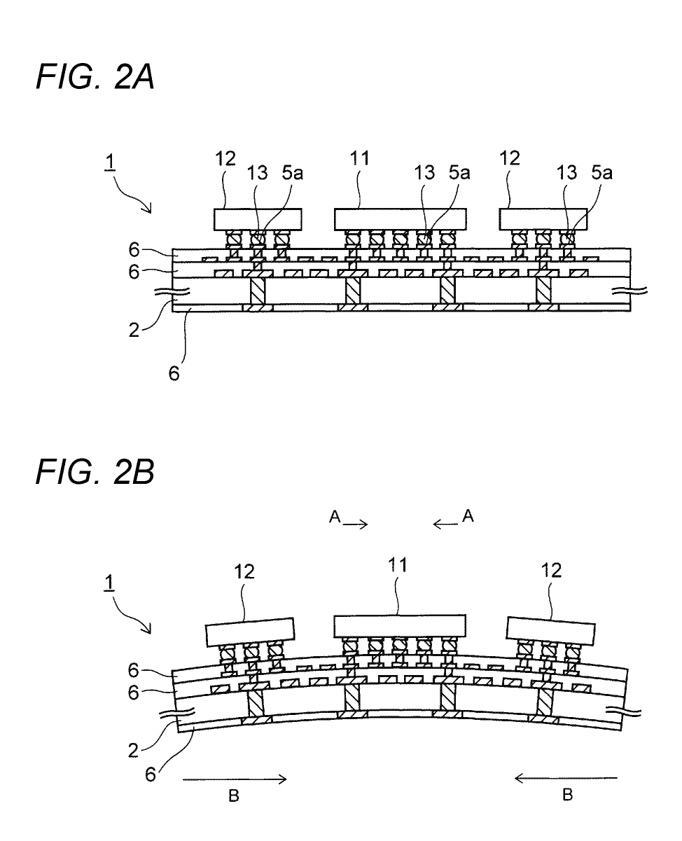

Successively, as shown in FIG. 2A, the solder bumps 13 are brought into abutment against the first electrode pads 5a. In this state, the solder bumps 13 are reflowed. Thus, the solder bumps 13 are melted by heating so that the circuit board 1 is connected to the respective semiconductor elements 11 and 12 through the solder bumps 13.

In the reflowing, the solder bumps 13 are melted surely. Accordingly, the solder bumps 13 are heated at a temperature of 220° C. or higher, which is higher than a melting point of the solder bumps 13.

Then, as shown in FIG. 2B, the circuit board 1 and the semiconductor elements 11 and 12 are cooled naturally up to a temperature of about 30° C.

On this occasion, thermal expansion coefficients of silicon and glass which can be used as the material of the substrate 2 are as small as 3 ppm/° C. and 3 ppm/° C. to 9 ppm/° C. respectively. A thermal expansion coefficient of the epoxy resin which is the material of the resin insulating layers 6 is as large as 20 ppm/° C. to 80 ppm/° C. Accordingly, the resin insulating layers 6 largely contract during the cooling. Following the contraction of the resin insulating layers 6, the circuit board 1 contracts largely as a whole.

On the other hand, the main material of each semiconductor element 11, 12 is silicon whose thermal expansion coefficient is as small as 3 ppm/° C. Accordingly, a contraction amount A of the semiconductor element 11, 12 is smaller than a contraction amount B of the circuit board 1.

Due to such a difference between the contraction amount A and the contraction amount B, the circuit board 1 warps with its upper side convex in this step.

Particularly, when the multilayer wiring layer 3 is formed only on one surface of the substrate 2 as in this example, balance of contractile force between opposite surfaces of the substrate 2 is lost. Accordingly, a conspicuous warp occurs in the circuit board 1.

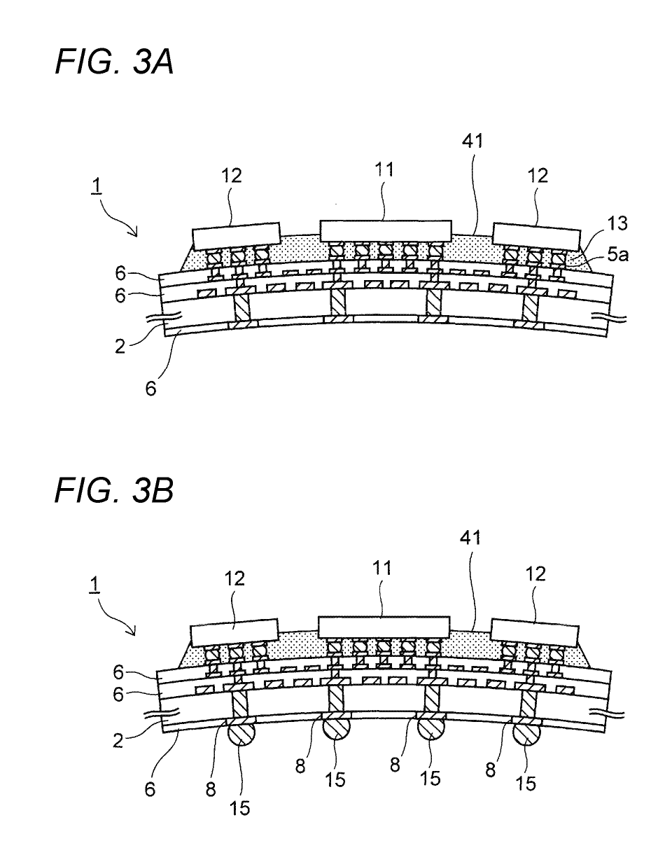

Next, as shown in FIG. 3A, a gap between the circuit board 1 and each semiconductor element 11, 12 is filled with an undertill resin 41. Thus, bonding strength between the circuit board 1 and the semiconductor element 11, 12 is enhanced.

Then, as shown in FIG. 3B, solder bumps 15 are bonded to the second electrode pads 8 of the circuit board 1.

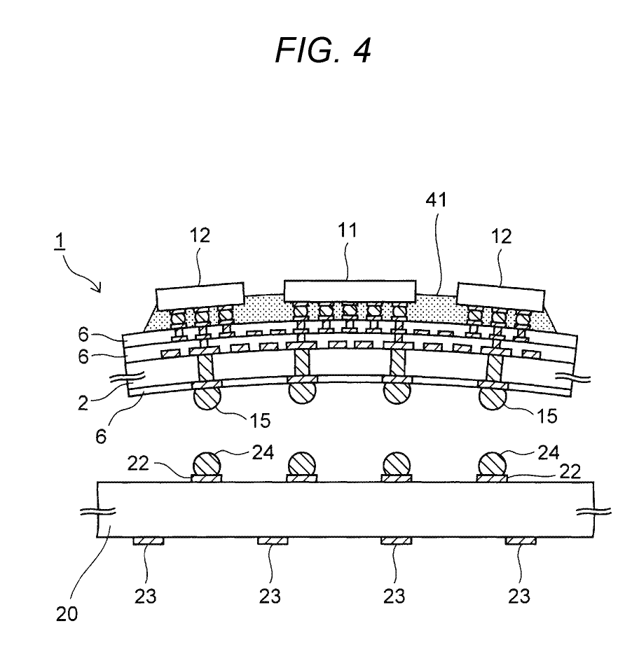

Successively, as shown in FIG. 4, a wiring substrate 20 is disposed under the circuit board 1.

The wiring substrate 20 is a package substrate which forms a semiconductor device together with the circuit board 1 and the semiconductor elements 11 and 12. The wiring substrate 20 includes third electrode pads 22 provided on its one main face, and fourth electrode pads 23 provided on the other main face.

Each copper layer is patterned to form the electrode pads 22, 23. Solder bumps 24 are bonded in advance on the third electrode pads 22.

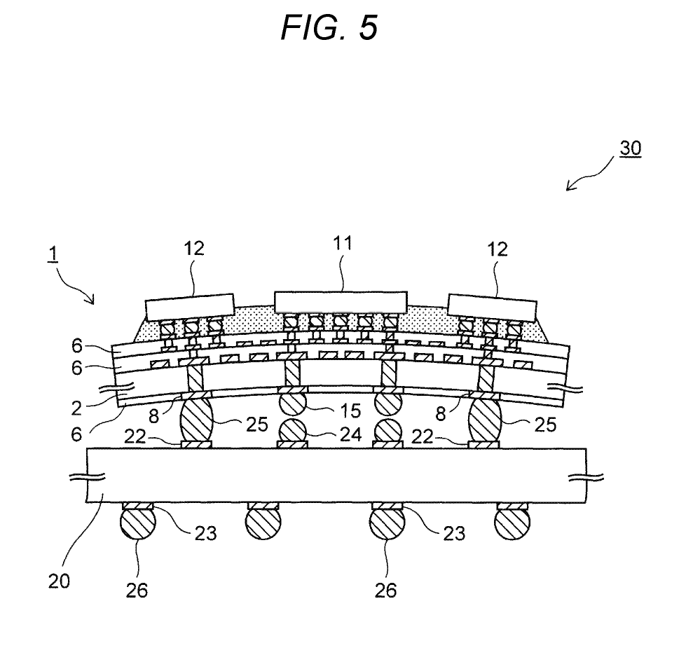

Next, as shown in FIG. 5, the solder bumps 15 and 24 which have been aligned with each other respectively are heated and melted with each other respectively. Thus, the circuit board 1 and the wiring substrate 20 are connected through solders 25 consisting of the solder bumps 15 and 24 melted with each other respectively.

On this occasion, the warp has occurred in the circuit board 1 as described above. Accordingly, ones of the solder bumps 15 and ones of the solder bumps 24 in the vicinity of the center of the circuit board 1 may fail in abutting against each other respectively so that connection failure may occur between these solder bumps 15 and 24.

Then, solder bumps are bonded as external connection terminals 26 to the fourth electrode pads 23 of the wiring substrate 20. Thus, a basic structure of a semiconductor device 30 according to this example is completed.

According to the aforementioned semiconductor device 30, silicon or glass which can be easily micromachined is used as the material of the substrate 2. Accordingly, the microfine through holes 2a and the microfine electrode pads 5a can be formed, so that the semiconductor elements 11 and 12 provided with the microfine solder bumps 13 can be mounted on the circuit board 1.

However, since the resin insulating layers 6 large in thermal expansion coefficient are formed on the substrate 2, the circuit board 1 warps and connection failure occurs at these solder bumps 15 and 24 in the vicinity of the center of the circuit board 1, as described above.

In addition, even when the solder bumps 15 and 24 are connected to each other respectively, the semiconductor elements 11 and 12 generate heat repeatedly under practical use to thereby cause deformation of the circuit board 1 repeatedly. As a result, cracking occurs at the solders 25 so that reliability of the semiconductor device 30 deteriorates.

The embodiments in each of which a circuit board can be suppressed from warping in the aforementioned manner will be described below.

### First Embodiment

A semiconductor device according to the present embodiment will be described following the sequence of manufacturing steps thereof.

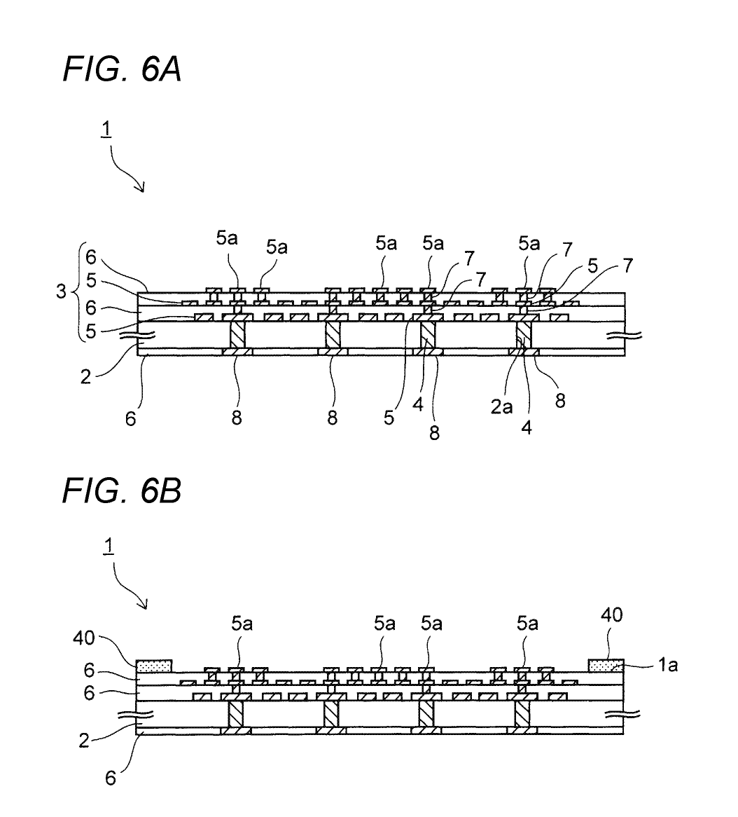

FIGS. 6A and 6B, FIGS. 7A and 7B, FIGS. 8A and 8B, FIGS. 9A and 9B and FIGS. 10 to 12 are sectional views in a process of manufacturing the semiconductor device according to the present embodiment. Incidentally, in FIGS. 6A and 6B, FIGS. 7A and 7B, FIGS. 8A and 8B, FIGS. 9A and 9B and FIGS. 10 to 12, constituent members the same as those which have been described in FIGS. 1A and 1B, FIGS. 2A and 2B, FIGS. 3A and 3B and FIGS. 4 and 5 will be referred to by the same signs as those in FIGS. 1A and 1B, FIGS. 2A and 2B, FIGS. 3A and 3B and FIGS. 4 and 5 respectively, and description thereof will be hereinafter omitted.

First, as shown in FIG. 6A, a circuit board 1 shown in FIGS. 1A and 1B is prepared as an interposer.

As described above with reference to FIGS. 1A and 1B, the circuit board 1 is provided with a substrate 2 made of an inorganic material such as silicon or glass which can be easily micromachined. In addition, a multilayer wiring layer 3 including wiring layers 5 and resin insulating layers 6 which are formed alternately to one another is provided on the substrate 2.

Next, as shown in FIG. 6B, a dispenser is used to form a thermosetting epoxy resin as a resin layer 40 on edges of one main face 1a of the circuit board 1. The epoxy resin is formed with a thickness of 0.1 mm to 0.7 mm e.g. about 0.5 mm. At this stage, the resin layer 40 is not thermally cured but uncured.

Although the material of the resin layer 40 is not limited particularly, SNC-762D made by Shin-Etsu Chemical Co., Ltd. is used as the material of the resin layer 40 in the present embodiment. The SNC-762D is an epoxy-based thermosetting resin with which a silica filler is kneaded and mixed, and whose thermosetting temperature is about 150° C.

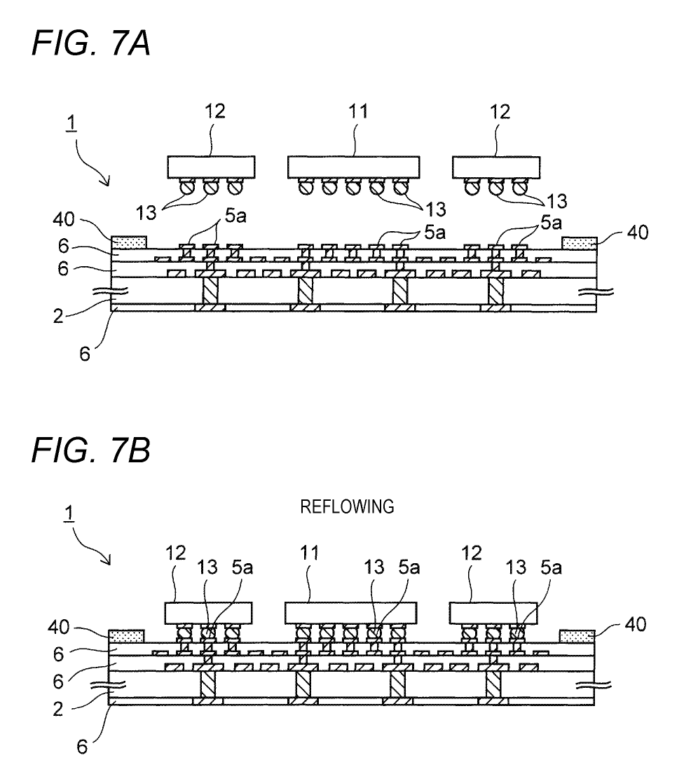

Next, as shown in FIG. 7A, first and second semiconductor elements 11 and 12 are disposed above the circuit board 1. Solder bumps 13 of the semiconductor elements 11 and 12 are aligned with first electrode pads 5a.

As described above, the first semiconductor element 11 is, for example, a CPU, and each of the second semiconductor elements 12 is, for example, a memory.

Incidentally, a plurality of semiconductor elements are not necessarily mounted on the circuit board 1 mixedly in this manner but only one first semiconductor element 11 may be mounted on the circuit board 1 alternatively.

Next, as shown in FIG. 7B, the semiconductor elements 11 and 12 are mounted on the first electrode pads 5a through the solder bumps 13. In this state, the solder bumps 13 are reflowed. Thus, the solder bumps 13 are melted by heating so that the semiconductor elements 11 and 12 are connected to the circuit board 1 through the solder bumps 13.

The reflowing condition is not limited particularly. For example, the reflowing may be performed under the condition that peak temperature of the solder bumps 13 is set at 250° C. while the solder bumps 13 are kept at a temperature of 220° C. or higher for forty-five seconds.

In the present embodiment, the resin layer 40 is also heated by the reflowing to be thermally cured. Accordingly, melting of the solder bumps 13 and thermal curing of the resin layer 40 can be performed simultaneously.

Incidentally, although the solder bumps 13 are provided on the semiconductor elements 11 and 12 in this example, solder bumps 13 may be formed in advance on the first electrode pads 5a and electrodes of the semiconductor elements 11 and 12 may be then connected to the solder bumps 13.

Further, solder bumps may be formed in advance on both the electrodes of the semiconductor elements 11 and 12 and the first electrode pads 5a, and the solder bumps on the both may be then connected to each other respectively.

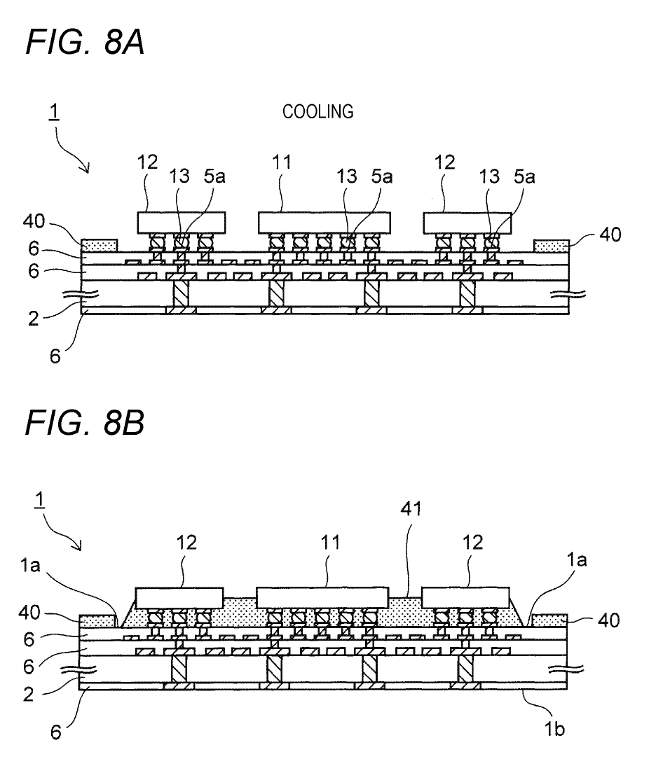

Then, as shown in FIG. 8A, the circuit board 1 and the semiconductor elements 11 and 12 are cooled naturally up to a temperature of about 30° C.

On this occasion, the circuit board 1 tends to warp due to a difference in thermal expansion coefficient between the circuit board 1 and each semiconductor element 11, 12. However, in the present embodiment, the resin layer 40 contracts to thereby correct the warp. Accordingly, it is possible to suppress the circuit board 1 from warping.

Particularly, the resin layer 40 has already been thermally cured at this point of time. Accordingly,contractile force of the resin layer 40 can act on the circuit board 1 without attenuating inside the resin layer 40 so that the warp of the circuit board 1 can be corrected efficiently.

In addition, in order to apply the contractile force from the resin layer 40 onto the circuit board 1 to correct the warp, it is preferable to form the resin layer 40 sufficiently larger in thermal expansion coefficient than silicon or glass which is the material of the substrate 2 occupying a major portion of the circuit board 1. In addition to the aforementioned epoxy resin having the thermal expansion coefficient of 20 ppm/° C. to 80 ppm/° C., a urethane resin having a thermal expansion coefficient of about 30 ppm/° C. to 190 ppm/° C. may be used as the material of such a resin layer 40.

Next, as shown in FIG. 8B, a gap between the circuit board 1 and each semiconductor element 11, 12 is filled with a thermosetting underfill resin 41.

In order to make it easy to fill the gap between the circuit board 1 and the semiconductor element 11, 12 with the underfill resin 41, it is preferable that a resin lower in viscosity than that of the resin layer 40 which has not been thermally cured yet is used as the underfill resin 41. For example, U8410-302 made by Namics Corporation may be used as such a resin. The U8410-302 is an epoxy-based thermosetting resin, whose thermosetting temperature is about 165° C.

On the other hand, the resin higher in viscosity than the underfill resin 41 is used as the material of the resin layer 40 which has not been thermally cured yet. Thus, the resin layer 40 which has not been thermally cured yet can be also prevented from getting wet and spreading onto the main face 1 a in the step of FIG. 6B.

Incidentally, in order to prevent stress from acting from the underfill resin 41 onto the first semiconductor element 11 and the second semiconductor elements 12 as sufficiently as possible, it is preferable that the composition of the underfill resin 41 is adjusted to make the thermal expansion coefficient of the underfill resin 41 lower than the thermal expansion coefficient of the resin insulating layers 6 or the resin layer 40. In consideration of this point, the thermal expansion coefficient of the underfill resin 41 is set at about 15 ppm/° C. to 25 ppm/° C. in the present embodiment.

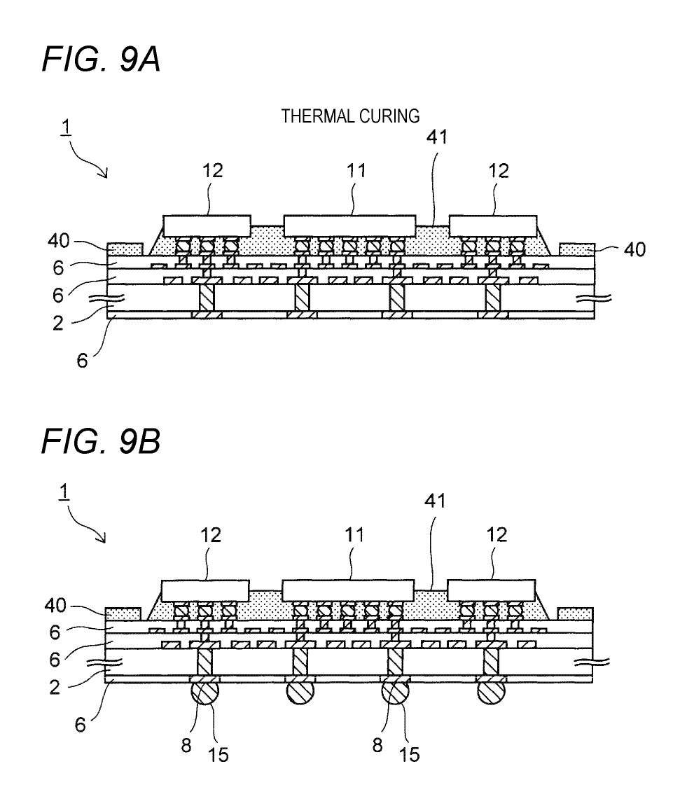

Next, as shown in FIG. 9A, the underfill resin 41 is heated at a temperature of 150° C. for two hours to be thermally cured. By the heat on this occasion, the resin layer 40 on the edges of the circuit board 1 is thermally cured completely.

Next, as shown in FIG. 9B, solder bumps 15 are bonded to second electrode pads 8 of the circuit board 1.

Successively, as shown in FIG. 10, a wiring board 20 which has been described in FIG. 4 is prepared, and solder bumps 24 are bonded on third electrode pads 22 provided on the wiring substrate 20.

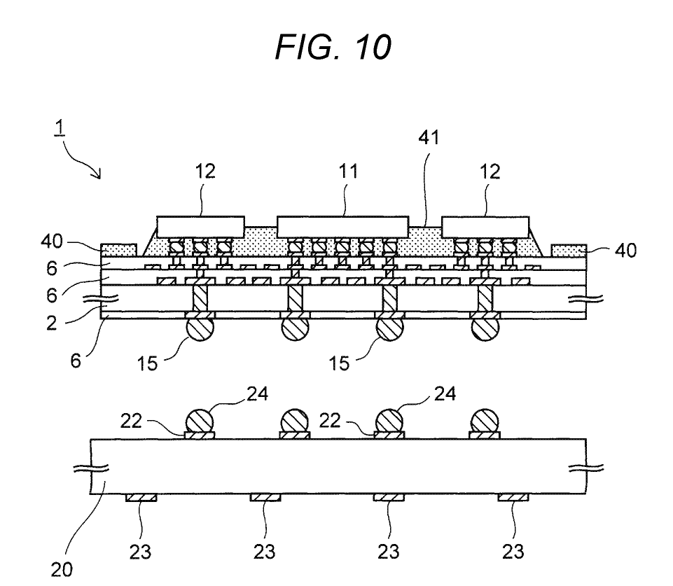

Next, as shown in FIG. 11, the solder bumps 15 and 24 which have been aligned with each other respectively are melted with each other respectively by heating. Thus, the circuit board 1 and the wiring substrate 20 are connected through solders 25 consisting of the solder bumps 15 and 24 melted with each other respectively.

On this occasion, the circuit board 1 is suppressed from warping as described above in the present embodiment. Accordingly, the solder bumps 15 and 24 can be prevented from being separate from each other respectively due to the warp so that the circuit board 1 and the wiring substrate 20 can be connected surely through the solders

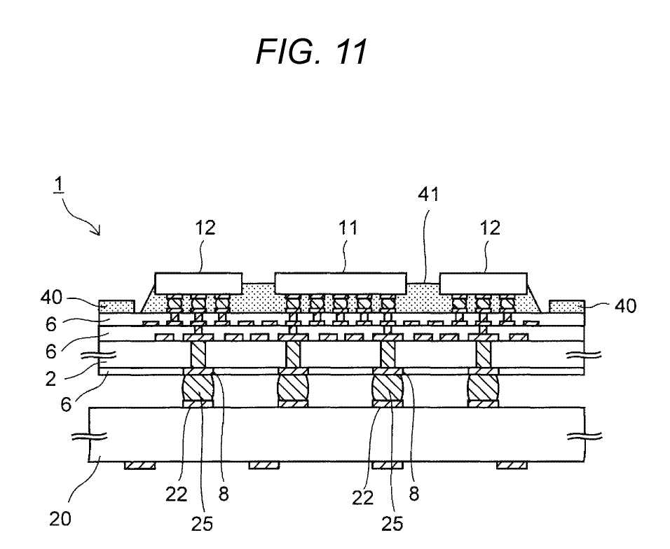

Then, as shown in FIG. 12, solder bumps are bonded as external connection terminals 26 to fourth electrode pads 23 of the wiring substrate 20. Thus, a basic structure of a semiconductor device 50 according to the present embodiment is completed.

The semiconductor device 50 is a BGA (Ball Grid Array) type semiconductor package which is mounted on a motherboard 51 under practical use. In addition, in order to expedite the semiconductor elements 11 and 12 to dissipate heat, a heatsink 52 made of metal such as copper may be fixed to upper surfaces 11a and 12a of the semiconductor elements 11 and 12.

Further, an electronic component such as a chip capacitor or an inductor may be mounted on the circuit board 1.

According to the present embodiment which has been described above, the resin layer 40 acts to correct the warp of the circuit board 1. Accordingly, flatness of the circuit board 1 can be secured so that the circuit board 1 and the wiring substrate 2 can be connected to each other surely.

When the resin layer 40 is too thin, sufficient contractile force for correcting the warp of the circuit board 1 may fail in acting from the resin layer 40 onto the circuit board 1. In order to prevent this, it is preferable that the resin layer 40 thicker than each of the resin insulating layers 6 of the circuit board 1 is formed so that sufficient contractile force can occur in the resin layer 40.

In order to further effectively suppress the circuit board 1 from warping, it is preferable that the resin layer 40 is formed to be thicker than the entire thickness of the multilayer wiring layer 3. As an example, it is preferable that the resin layer 40 is formed to be four times to fifty times, e.g. five times or more, as thick as the entire thickness of the multilayer wiring layer 3.

Incidentally, when the resin layer 40 is too thick, a contraction amount of the resin layer 40 becomes too large when the circuit board 1 is cooled in the step of FIG. 8A. Accordingly, the circuit board 1 may warp with the other main face 1b convex. In addition, it is also difficult to fix the heatsink 52 to the upper surfaces of the semiconductor elements 11 and 12 because the thick resin layer 40 becomes an obstacle to the heatsink 52.

Therefore, it is preferable that the resin layer 40 is formed to be thin enough to make height of an upper surface 40a of the resin layer 40 lower than the upper surface 11a, 12a of each semiconductor element 11, 12.

In addition, the conspicuous warp of the circuit board 1 occurs when the multilayer wiring layer 3 is formed only on one surface of the substrate 2 as described above. Accordingly, it is particularly highly advantageous to suppress the warp of the circuit board 1 due to the resin layer 40 when the multilayer wiring layer 3 is formed only on one surface of the substrate 2.

Next, various examples of a planar layout of the resin layer 40 will be described.

### FIRST EXAMPLE

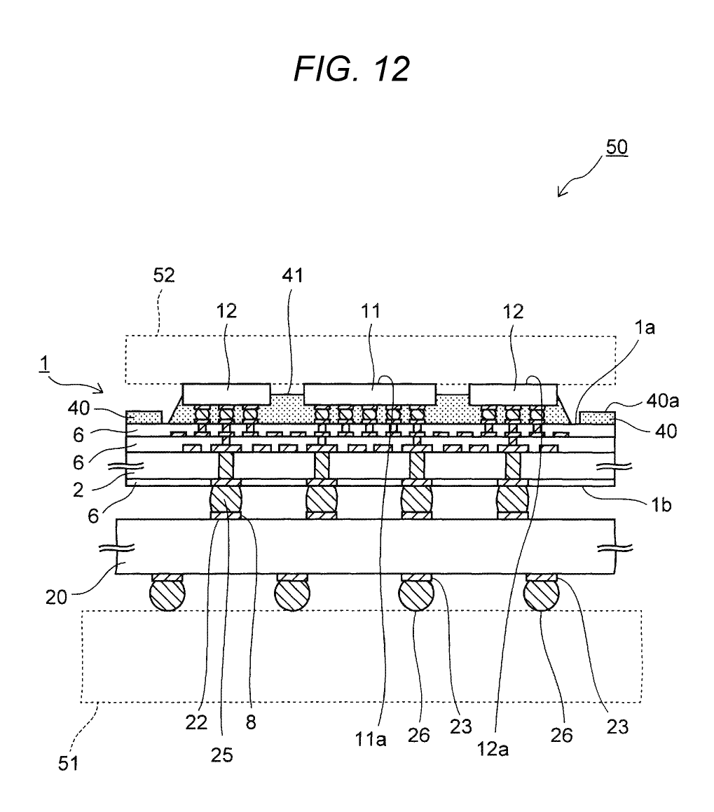

FIG. 13 is a plan view showing a planar layout of a resin layer 40 according to a first example.

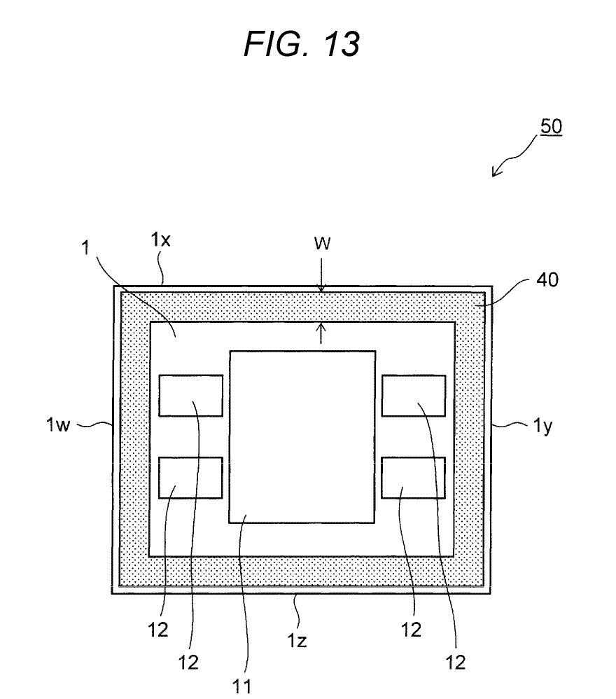

Incidentally, in FIG. 13, the underfill resin 41 is omitted in order to prevent the drawing from being complicated. The same thing will be also applied to FIGS. 14 to 17 which will be described later.

As shown FIG. 13, the resin layer 40 is formed on the main face 1a of the circuit board 1 to completely surround the semiconductor elements 11 and 12.

In addition, in this example, the resin layer 40 is shaped like a frame in plan view to extend along four sides 1w, 1x, 1y and 1z of the circuit board 1 shaped like a rectangle. Here, the side 1x and the side 1z are opposite to each other, and the side 1w and the side 1y are opposite to each other. The side 1w and the side 1y are connected to the sides 1x and the side 1z. In other words, the side 1w and the side 1y are positioned between the side 1x and the side 1z.

When the resin layer 40 is shaped like the frame in this manner, contractile force acts uniformly from the resin layer 40 onto the sides 1w, 1x, 1y and 1z when the circuit board 1 is cooled in the step of FIG. 8A. Accordingly, the warp can be corrected uniformly all over the circuit board 1.

Incidentally, a width W of the resin layer 40 is not limited particularly. The width W is set at 0.5 mm to 3 mm, e.g. about 2 mm. The same thing will be also applied to second to fifth examples which will be described below.

### SECOND EXAMPLE

FIG. 14 is a plan view showing a planar layout of a resin layer 40 according to a second example. As shown in FIG. 14, the resin layer 40 is formed on the main face 1a of the circuit board 1 so as to discontinuously (intermittently) surround the semiconductor elements 11 and 12. In this example, the resin layer 40 also extends along four sides 1w, 1x , 1y and 1z of the circuit board 1. Accordingly, the warp can be corrected uniformly all over the circuit board 1.

### THIRD EXAMPLE

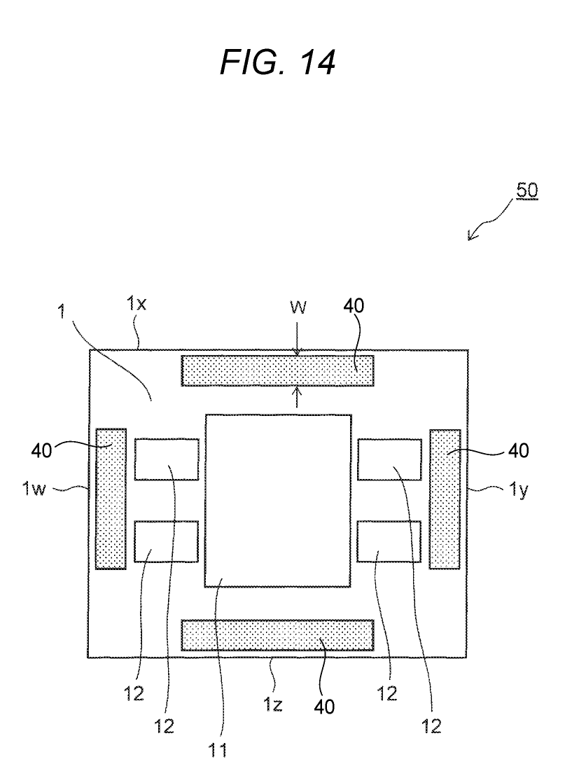

FIG. 15 is a plan view showing a planar layout of a resin layer 40 according to a third example.

Also in this example, the resin layer 40 is formed on the main face 1a of the circuit board 1 in peripheries of the semiconductor elements 11 and 12.

In addition, in this example, when viewed in a plan view, the resin layer 40 is formed into belt shapes to extend along respective edges of two opposite sides 1x and 1z of the circuit board 1. More specifically, the resin layer 40 has a resin layer 40a (an example of a first resin layer) which is formed into a belt shape to extend along the side 1x (an example of a first side) of the circuit board 1, and a resin layer 40b (an example of a second resin layer) which is formed into a belt shape to extend along the side 1z (an example of a second side) of the circuit board 1.

Such a layout is particularly effective in a case where the second semiconductor elements 12 are provided near to respective sides 1w and 1y of the circuit board 1 and there is therefore no space for forming the resin layer 40 in the vicinities of the sides 1w and 1y.

In this case, the resin layer 40 is formed thus to extend along the two opposite sides 1x and 1z. Accordingly, contractile force of the resin layer 40 acts on the circuit board 1 with better balance than in a case where the resin layer 40 is formed to extend along one of the sides 1x and 1z. As a result, the circuit board 1 can be flattened easily.

### FOURTH EXAMPLE

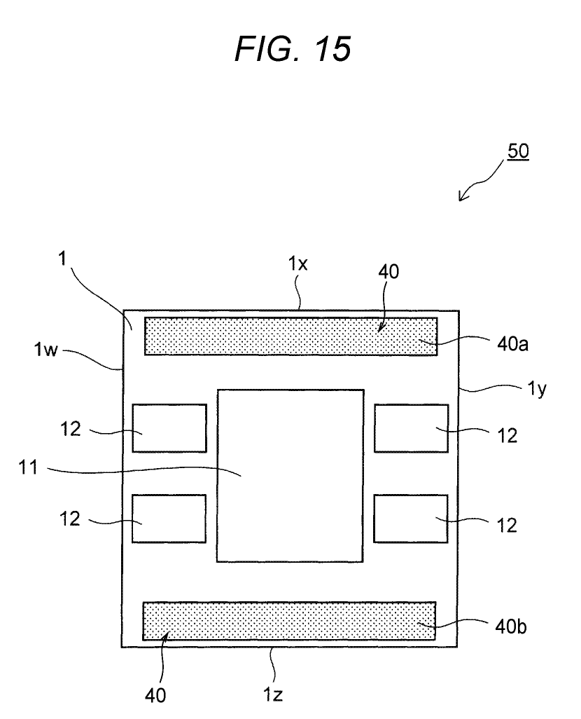

FIG. 16 is a plan view showing a planar layout of a resin layer 40 according to a fourth example.

In this example, the resin layer 40 formed on the main face 1a of the circuit board 1 has resin layers 40a to 40f. As described above in the third example, the resin layer 40a is formed into a belt shape to extend along a side 1x of the circuit board 1. The resin layer 40b is formed into a belt shape to extend along a side 1z of the circuit board 1. The resin layer 40c (an example of a third resin layer) is connected to one end of the resin layer 40a and extends along a side 1w (an example of a third side) of the circuit board 1. The resin layer 40d (an example of a fourth resin layer) is connected to the other end of the resin layer 40a and extends along a side 1y (an example of a fourth side) of the circuit board 1. The resin layer 40e (an example of a fifth resin layer) is connected to one end of the resin layer 40b and extends along the side 1w of the circuit board 1. The resin layer 40f (an example of a sixth resin layer) is connected to the other end of the resin layer 40b and extends along the side 1y of the circuit board 1. The resin layers 40c and 40d may be formed integrally with the resin layer 40a. The resin layers 40e and 40f may be formed integrally with the resin layer 40b in a similar manner or the same manner. The resin layers 40c to 40f may be also formed into belt shapes.

According to this example, contractile force of the resin layer 40 also acts on the respective sides 1w and 1y due to the resin layers 40c to 40f. Accordingly, balance of contractile force acting from the resin layer 40 onto the circuit board 1 is more excellent than that in the third example. As a result, flatness of the circuit board 1 is improved.

### FIFTH EXAMPLE

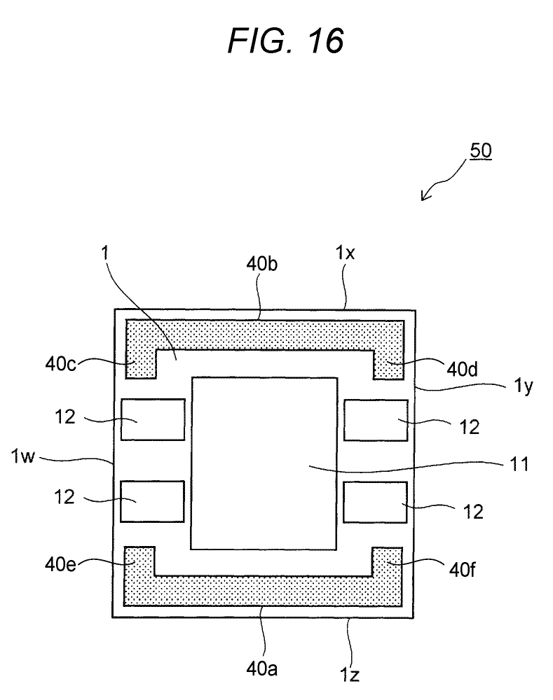

FIG. 17 is a plan view showing a planar layout of a resin layer 40 according to a fifth example.

In this example, the resin layer 40 is also formed on the main face 1a of the circuit board 1 in peripheries of the semiconductor elements 11 and 12, similarly to the first to fourth examples.

In this example, when viewed in plan view, the resin layer 40 is formed into belt shapes along diagonal lines L of the rectangular circuit board 1.

Thus, contractile force acting from parts of the resin layer 40 onto the circuit board 1 when the circuit board 1 is cooled in the step of FIG. 8A is symmetrical with respect to the center of the circuit board 1. Accordingly, a warp of the circuit board 1 can be corrected uniformly by the contractile force.

Next, an examination which was conducted by the present inventor will be described.

In the examination, it was checked whether the warp of the circuit board 1 could be really suppressed or not by the resin layer 40 which was formed in the aforementioned manner.

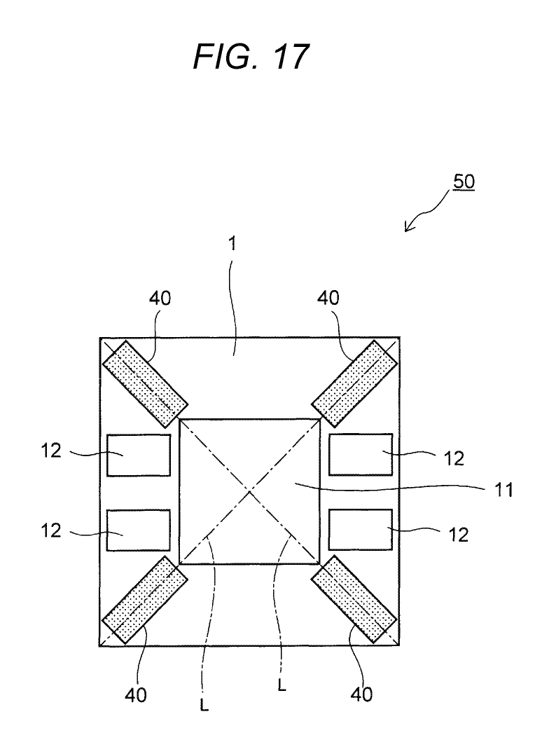

FIG. 18 is a sectional view for explaining a method of the examination.

In the examination, a jig 61 was placed on a transparent substrate 60 made of glass and the circuit board 1 was mounted on the jig 61, as shown in FIG. 18.

While hot air 62 was supplied from sides of the circuit board 1 in this state to heat the circuit board 1, laser light 63 was radiated onto the other face 1b of the circuit board 1 through the transparent substrate 60. The laser light 63 was outputted from a laser range finder 64 and a warp amount of the circuit board 1 was measured based on reflected light of the laser light 63.

Incidentally, the warp amount is defined as a change amount of a distance D between the center of the other main face 1b of the circuit board 1 and the transparent substrate 60.

In addition, the layout of the aforementioned fourth example (FIG. 16) was used as the layout of the resin layer 40. A board which was 35 mm square and 0.3 mm thick was used as the circuit board 1 used in the examination.

The first semiconductor element 11 was formed into a rectangle which was 24 mm long on long side, 20 mm long on short side and 0.5 mm thick. Further, each of the second semiconductor elements 12 was formed into a rectangle which was 7.3 mm long on long side, 5.5 mm long on short side and 0.5 mm thick.

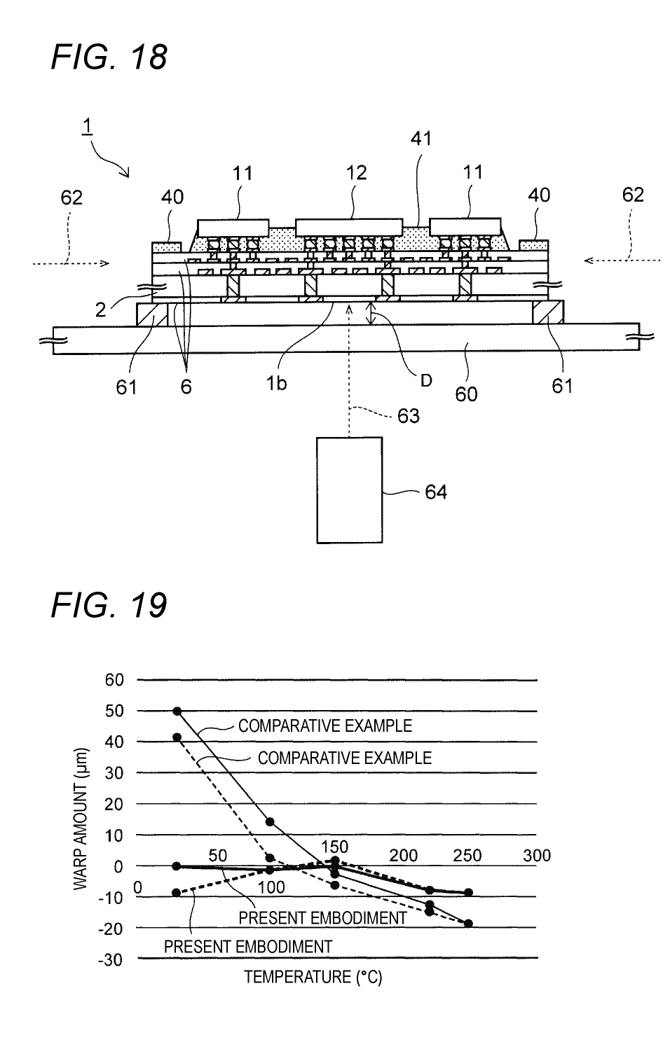

FIG. 19 is a graph showing measurement results of warp amounts in this case.

In FIG. 19, the abscissa expresses temperature of each circuit board 1, and the ordinate expresses a warp amount of the circuit board 1.

In the examination, two samples in each of which the resin layer 40 had been removed from the circuit board 1 were produced as comparative examples, and warp amounts as to the comparative examples were measured. Incidentally, two samples according to the present embodiment were also prepared and warp amounts of the two samples were measured respectively.

Further, in each of the samples of e present embodiment, an epoxy resin was used as the material of the resin layer 40. The resin layer 40 was 2 mm wide and 0.5 mm thick. Incidentally, the material of the substrate 2 was glass and the material of each semiconductor element 11, 12 was silicon.

In each of the comparative examples, the warp amount increases more conspicuously as the temperature is lower, as shown in FIG. 19.

On the other hand, according to each of the samples of the present embodiment, the warp amount is substantially zero even at a low temperature of about 30° C. Consequently, it has been obvious that the warp of the circuit board 1 at the low temperature can be corrected.

Moreover, according to the sample of the present embodiment, the warp amount substantially did not change even when the temperature was increased from 30° C. Accordingly, even when temperature of heat generated by each semiconductor element 11, 12 under practical use fluctuates, flatness of the circuit board 1 can be maintained. Consequently, the solders 25 (FIG. 11) can be suppressed from cracking due to deformation of the circuit board 1. As a result, reliability of a semiconductor device 50 can be improved.

### Second Embodiment

In the first embodiment, the circuit board 1 and each semiconductor element 11, 12 are connected through the solder bumps 13 which are melted by reflowing, as shown in FIG. 7B.

On the other hand, in the present embodiment, a circuit board 1 and each semiconductor element 11, 12 are connected by a TCB (Thermal Compression Bonding) method as follows.

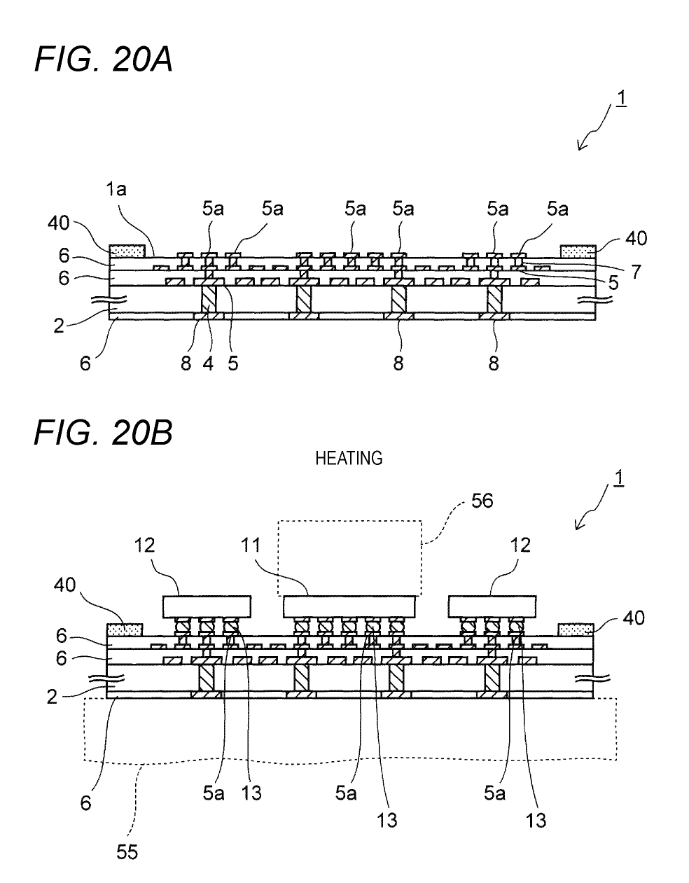

FIGS. 20A and 20B, FIGS. 21A and 21B and FIGS. 22A and 22B are sectional views in a process of manufacturing a semiconductor device according to the present embodiment.

Incidentally, in FIGS. 20A and 20B, FIGS. 21A and 21B and FIGS. 22A and 22B, constituent members the same as those which have been described in the first embodiment will be referred to by the same signs as those in the first embodiment respectively, and description thereof will be hereinafter omitted.

First, the step of FIGS. 6A and 6B in the first embodiment is performed. As a result, a structure in a resin layer 40 is formed on edges of one main face 1a of a circuit board 1 is obtained, as shown in FIG. 20A.

As described above, the resin layer 40 is made of a thermosetting epoxy resin. At this stage, the resin layer 40 is uncured.

Next as shown in FIG. 20B, the circuit board 1 is mounted on a stage 55 heated at a temperature of about 100° C. Accordingly, the circuit board 1 is preheated by the heat of the stage 55.

While a first semiconductor element 11 is sucked by a heating head 56, the first semiconductor element 11 is mounted onto first electrode pads 5a through solder bumps 13.

Further, while the semiconductor element 11 is pressed by the heating head 56, temperature of the heating head 56 is increased to about 300° C. to melt the solder bumps 13. A heating time on this occasion is not limited particularly but may be set at about four seconds in the present embodiment.

Thus, the circuit board 1 and the first semiconductor element 11 are connected through the solder bumps 13.

Thus, the method for mounting the first semiconductor element 11 on the circuit board 1 using the heating head 56 is called TCB method.

In the TCB method, the resin layer 40 is also heated by the heat of the heating head 56 to be thermally cured. Accordingly, a step of thermally curing the resin layer 40 can be dispensed with.

Incidentally, second semiconductor elements 12 are also mounted on the circuit board 1 by the TCB method.

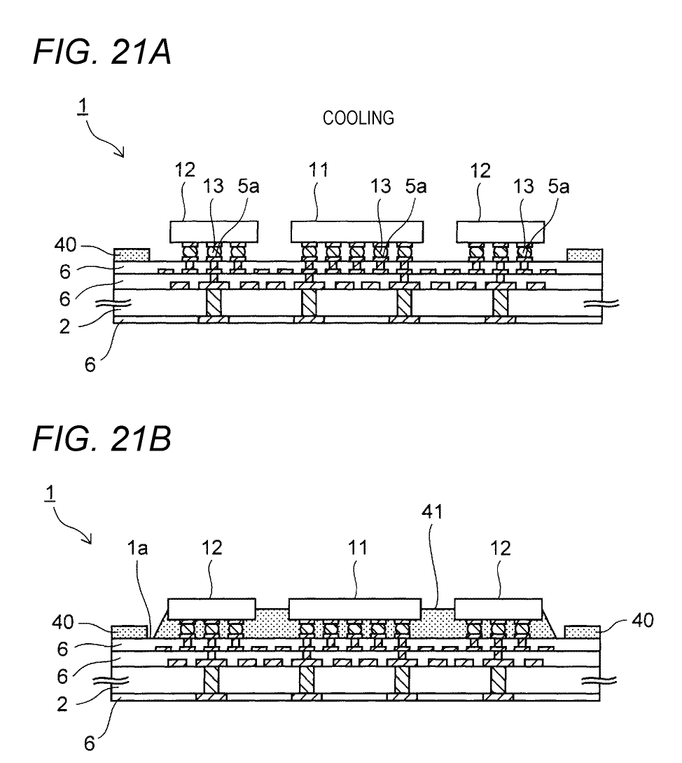

Next, as shown in FIG. 21A, the circuit board 1 and each semiconductor element 11, 12 are cooled naturally up to a temperature of about 30° C.

On this occasion, the circuit board 1 tends to warp due to a difference in thermal expansion coefficient between the circuit board 1 and the semiconductor element 11, 12. However, the resin layer 40 contracts during the cooling to thereby correct the warp of the circuit board 1 in a similar manner to or the same manner as in the first embodiment. Accordingly, the circuit board 1 can be suppressed from warping.

Next, as shown in FIG. 21B, a gap between the main face 1a of the circuit board 1 and each semiconductor element 11, 12 is filled with a thermosetting underfill resin 41. For example, U8410-302 made by Namics Corporation is used as the undertill resin 41.

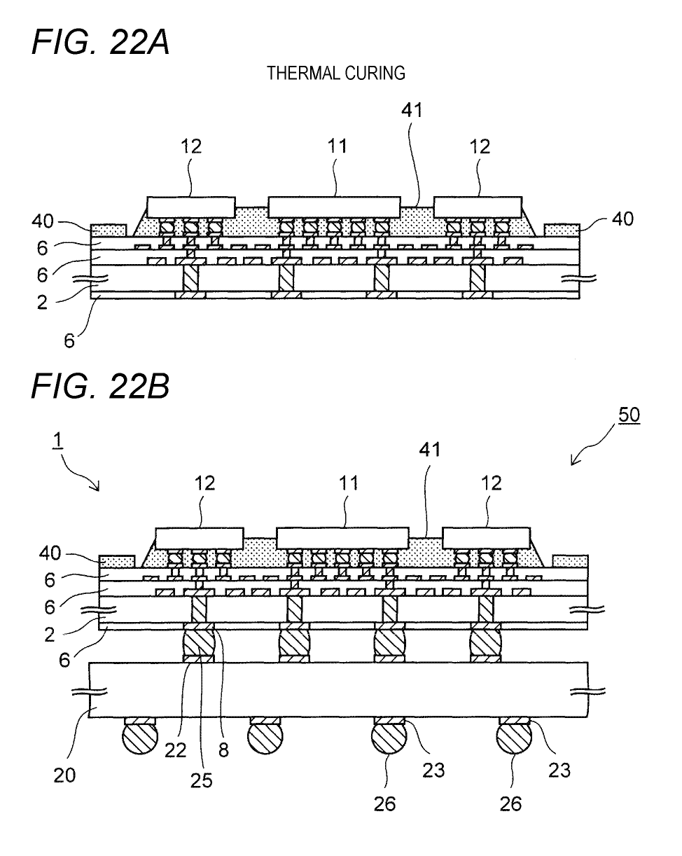

Successively, as shown in FIG. 22A, the underfill resin 41 is heated at a temperature of 150° C. for two hours to be thermally cured. By the heat on this occasion, the resin layer 40 on the edges of the circuit board 1 is thermally cured completely.

Then, the steps of FIGS. 9B to FIG. 12 which have been described in the first embodiment are performed. As a result, a basic structure of a semiconductor device 50 according to the present embodiment is completed, as shown in FIG. 22B.

According to the present embodiment which has been described above, the resin layer 40 is thermally cured when the solder bumps 13 are melted by heating in the step of FIG. 20B. Accordingly, a step of thermally curing the resin layer 40 can be dispensed with so that the process can be simplified.

### Third Embodiment

In the second embodiment, after each semiconductor element 11, 12 is mounted on the circuit board 1 by the TCB method, the gap between the circuit board 1 and the semiconductor element 11, 12 is filled with the underfill resin 41, as shown in FIG. 20B to FIG. 21B.

On the other hand, in the present embodiment, after an upper side of a circuit board 1 is coated with an underfill resin 41, each semiconductor element 11, 12 is mounted on the circuit board 1, as will be described below.

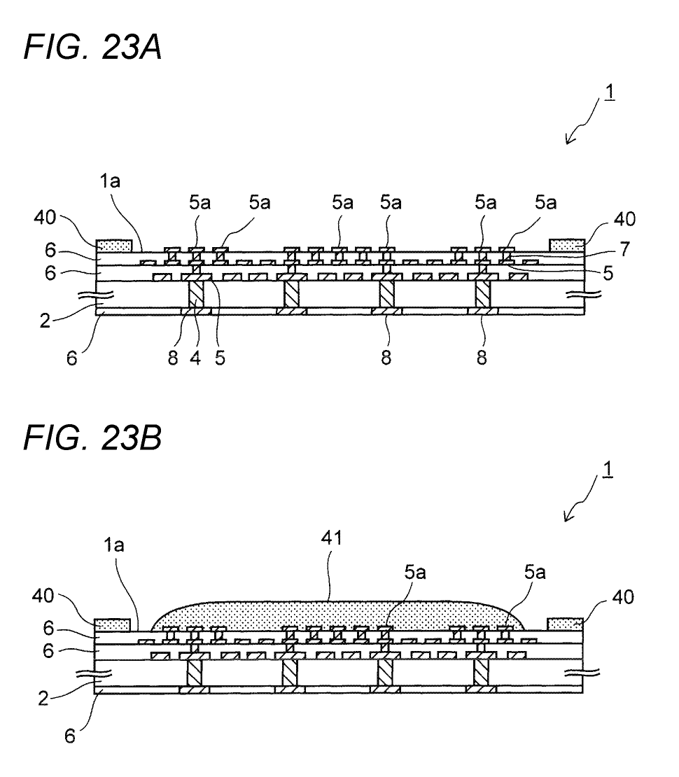

FIGS. 23A and 23A, FIGS. 24A and 24B and FIG. 25 are sectional views in a process of manufacturing a semiconductor device according to the present embodiment.

Incidentally, in FIGS. 23A and 23A, FIGS. 24A and 24B and FIG. 25, constituent members the same as those which have been described in the first embodiment or the second embodiment will be referred to by the same signs as those in these embodiments, and description thereof will be hereinafter omitted.

First, the step of FIGS. 6A and 6B in the first embodiment is performed. As a result, a structure in which a resin layer 40 is formed on edges of one main face 1a of the circuit board 1 is obtained, as shown in FIG. 3A.

The resin layer 40 is made of a thermosetting epoxy resin in a similar manner to or the same manner as in the first embodiment. At this stage, the resin layer 40 is uncured.

Next, as shown in FIG. 23B, a dispenser is used to apply the thermosetting underfill resin 41 to a portion of the main face 1a of the circuit board 1, from which the resin layer 40 is absent. The material of the underfill resin is not limited particularly. U8410-302 made by Namics Corporation may be used as the underfill resin 41 in a similar manner to or the same manner as in the first embodiment.

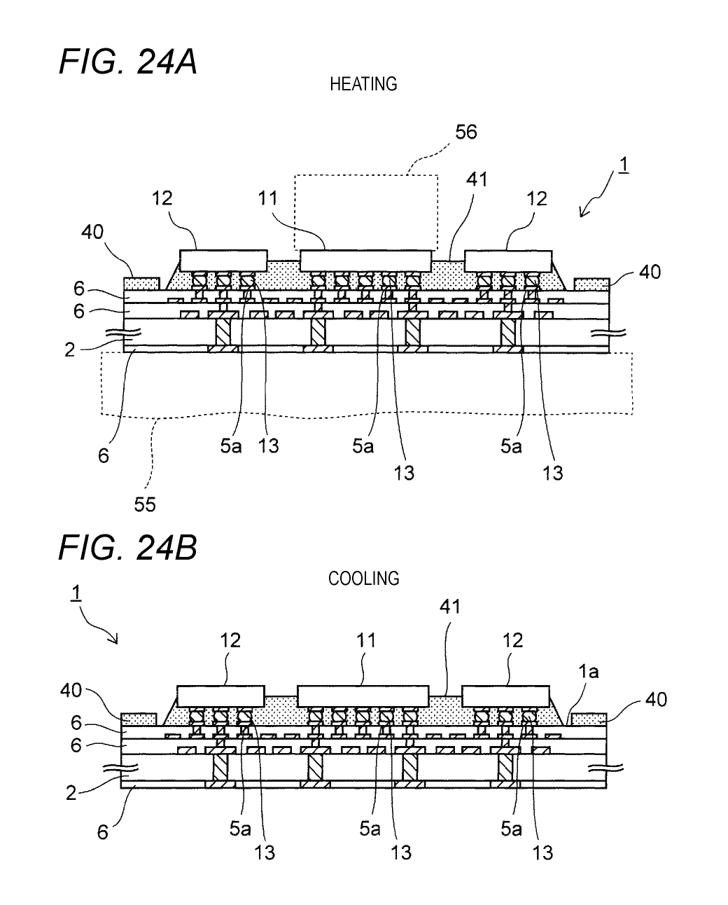

Successively, as shown in FIG. 24A, the circuit board 1 is mounted on a stage 55 heated at a temperature of about 100° C. Accordingly, the circuit board 1 is preheated by the heat of the stage 55.

While the first semiconductor element 11 is sucked by a heating head 56, the first semiconductor element 11 is mounted onto the main face 1a of the circuit board 1 with the underfill resin 41 interposed between the main face 1a and the first semiconductor element 11.

Then, the semiconductor element 11 is pressed by the heating head 56 to make solder bumps 13 abut against the first electrode pads 5a. Further, temperature of the heating head 56 is increased to about 300° C. to melt the solder bumps 13. Incidentally, the heating temperature of the heating head 56 is kept, for example, for about four seconds.

Thus, the circuit board 1 and the first semiconductor element 11 are connected through the solder bumps 13 by the TCB method, and the resin layer 40 and the underfill resin 41 are thermally cured simultaneously by the heat of the heating head 56.

Incidentally, second semiconductor elements 12 are also mounted on the circuit board 1 by the TCB method.

Next, the circuit board 1 and each semiconductor element 11, 12 are naturally cooled up to a temperature of about 30° C., as shown in FIG. 24B.

Even when the circuit board 1 tends to warp due to a difference in thermal expansion coefficient between the circuit board 1 and the semiconductor element 11, 12 on this occasion, the resin layer 40 contracts to thereby correct the warp. Accordingly, flatness of the circuit board 1 is maintained.

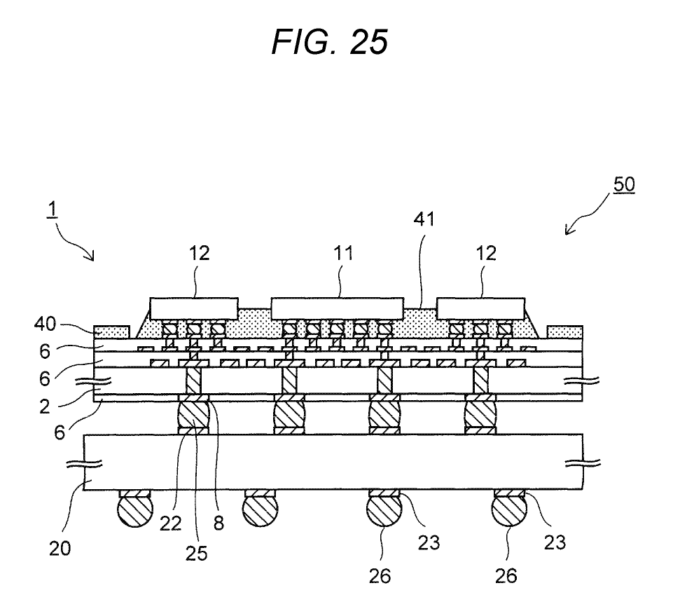

Then, the steps of FIG. 9B to FIG. 12 which have been described in the first embodiment are performed. Thus, a basic structure of a semiconductor device 50 according to the present embodiment is completed, as shown in FIG. 25.

According to the present embodiment which has been described above, when the solder bumps 13 are melted by heating in the step of FIG. 24A, the resin layer 40 and the underfill resin 41 are thermally cured simultaneously. Accordingly, a step of thermally curing the resin layer 40 and the underfill resin 41 can be dispensed with so that the process can be simplified.

As described above, the exemplary embodiment and the modification are described in detail. However, the present invention is not limited to the above-described embodiment and the modification, and various modifications and replacements are applied to the above-described embodiment and the modifications without departing from the scope of claims.

Various aspects of the subject matter described herein are set out non-exhaustively in the following numbered clauses:

1) A method of manufacturing a semiconductor device, the method comprising:

a) providing a circuit board, wherein the circuit board comprises a substrate made of an inorganic material and a resin insulating layer formed on the substrate;

b) forming a resin layer on a main face of the circuit board such that the resin layer extends along sides or diagonal lines of the circuit board; and

c) mounting a semiconductor element including a bump on the main face of the circuit board after the step b),

wherein the step c) comprises c1) melting the hump by eating to thereby connect the circuit board and the semiconductor element to each other through the bump.

2) The method according to clause (1), wherein the resin layer is made of a thermosetting resin, and

in the step c1), the resin layer is thermally cured.

3) The method according to clause (1), further comprising:

d) filling a gap between the main face of the circuit board and the semiconductor element with an underfill resin,

wherein the resin layer is made of a resin whose viscosity is higher than that of the underfill resin.

4) The method according to clause (2), wherein

the resin layer is made of a thermosetting resin,

the method further comprises d) providing an underfill resin on the main face of the circuit board,

the step d) is performed prior to the step c), and

in the step c1), the resin layer and the underfill resin are thermally cured simultaneously.

What is claimed is:

1. A semiconductor device comprising:
a circuit board comprising a substrate made of an inorganic material, and a resin insulating layer formed on the substrate;
a semiconductor element mounted on a main face of the circuit board through a bump; and
a resin layer formed on the main face to extend along sides or diagonal lines of the circuit board, wherein a thermal expansion of the resin layer is larger than that of the substrate.

2. The semiconductor device according to claim 1, wherein the resin layer is formed on the main face to surround the semiconductor element.

3. The semiconductor device according to claim 2, wherein the resin layer is formed on the main face to completely surround the semiconductor element.

4. The semiconductor device according to claim 1, wherein the resin layer comprises:
a first resin layer that is formed into a belt shape to extend along a first side of the circuit board; and
a second resin layer that is formed into a belt shape to extend along a second side of the circuit board that is opposite to the first side.

5. The semiconductor device according to claim 4, wherein the resin layer further comprises:
a third resin layer that is connected to one end of the first resin layer to extend along a third side of the circuit board;
a fourth resin layer that is connected to the other end of the first resin layer to extend along a fourth side of the circuit board;
a fifth resin layer that is connected to one end of the second resin layer to extend along the third side; and
a sixth resin layer that is connected to the other end of the second resin layer to extend along the fourth side,
the third side and the fourth side are opposite to each other and connected to the first side and the second side.

6. The semiconductor device according to claim 1, wherein a level of an upper surface of the resin layer is lower than that of an upper surface of the semiconductor element.

7. A semiconductor device according to claim 1, wherein the resin layer is thicker than the resin insulating layer.
